(19) United States
(12) Patent Application Publication
(10) Pub. No.: US 2003/0174540 A1
(43) Pub. Date: Sep. 18, 2003

(54) Device and method for converging erased flash memories

(76) Inventors: Tso-Hung Fan, Taipei (TW); Chih-Chieh Yeh, Taipei (TW); Tao-Cheng Lu, Kaohsiung (TW)

Correspondence Address: BIRCH STEWART KOLASCH & BIRCH, PO BOX 747, FALLS CHURCH, VA, 22040-0747, US

(21) Appl. No.: 10/283,192

(22) Filed: Oct. 30, 2002

(30) Foreign Application Priority Data
Mar. 15, 2002 (TW) 91104949

(51) Int. Cl. G11C 11/34

(52) U.S. Cl. 365/185.29

(57) ABSTRACT

A device for converging an erased flash memory array. The memory array includes a plurality of memory cells, each memory cell having a control gate, a floating gate, a source, and a drain. The drain voltage supply is coupled to the drain for providing a positive drain voltage. The constant current supply is coupled to the source for providing a source current. The control gate power supply is coupled to the control gate for providing a gradually increasing gate voltage to the control gate to control the source current flowing through the memory cell and adjust the threshold voltage of the memory cells.

### BACKGROUND OF THE INVENTION

1. Field of the Invention

The present invention relates in general to a device and a method for converging erased flash memory cells. In particular, the present invention relates to a device and a method for converging erased flash memory cells by increasing control gate voltage.

2. Description of the Related Art

Flash memory devices that can be programmed and erased by electronic operations such as applying different voltages have become widely used memory module types.

Conventional programming and erasing procedures for flash memory cells are described as follows. Programming or storing data is achieved by channeling hot electrons. In detail, a strong electric field, induced by the potential difference between the coupled positive voltage of the floating gate and the voltage of the channel, can provide electrons with enough kinetic energy to penetrate the oxide layer. Thus, these hot electrons are trapped in the floating gate. The presence or absence of the electrons trapped in the floating gate affects the conducting state of channels beneath the floating gate. Thus, each memory cell can be programmed to store a “1” or “0” according to the absence or presence of the trapped charges in the floating gate.

Erasing or deleting data is achieved by releasing the trapped charges in the floating gate by Flowler-Nordheim (F-N) tunneling. A huge negative voltage is directly applied to the control gate and coupled to the floating gate for driving the trapped electrons in the floating gate to tunnel the oxide layer and to be released through the channel beneath the floating gate or through the source region.

However, flash memory suffers from over-erasing after erasing. That is, the threshold voltage of flash memory cell becomes negative or ultra low. In addition, the threshold voltage distribution of memory cells in a similar state is extended. The cells with ultra low threshold voltage will induce large leakage, while the cells with higher threshold voltage will degrade read current, especially in multi-level-cell per bit Flash.

Thus, converge process is performed after the flash memory array is erased to improve the state of the flash memory cells. FIG. 1 shows the circuit used to perform conventional converge process.

A memory array 10 comprises a plurality of memory cells 12A, 12B, 12C, and 12D. The memory cells are flash memories. FIG. 2 shows the structure of the flash memory. Flash memory comprises a control gate 122, a floating gate 124, a drain 126 and a source 128. Here, the structure of the flash memory cells 12B, 12C, and 12D are the same as the flash memory cell 12A.

The voltage applied to the drain is 4V, and the source is coupled to a power supply to receive the current of about 2 mA. In addition, the control gate of the conventional flash memory cell receives 3V constant voltage to perform convergence after erasing. Here, the executing time is 10 ms. By convergence, the threshold voltage of the over-erasing flash memory cell is adjusted to a predetermined value.

FIG. 3A shows the voltage applied to the control gate and the drain to perform the conventional converge process. FIG. 3B shows the threshold voltage distribution of flash memory cells. Here, the drain and the gate receive constant voltage.

When the threshold voltage of a flash memory cell becomes negative or ultra low because of over-erasing, the threshold voltage of the flash memory cell is not adjusted while the control gate voltage is a constant 3V. At this time, most current provided by the constant power supply 14 flows through the memory cell B with ultra low threshold voltage and little flows through the memory cell A with the threshold voltage higher than memory cell B.

As shown in FIG. 3B, the cell A is not adjusted. Moreover, the constant power supply 14 is shut down when the current flowing through the memory cell B is higher than the default current of the constant power supply 14. Thus, convergence is stopped.

FIG. 4 shows the read disturb characteristics of 100&100K P/E cycled cell with conventional converge process, cell dimension of which is W/L=0.3/0.3 um. In FIG. 4, the memory cell A shows an abrupt increase in threshold voltage shift around 10³ seconds in both 100&100K P/E cycling cases. Thus, the reliability of the memory cell A is affected.

### SUMMARY OF THE INVENTION

The object of the present invention is to provide a device and a converge method for erasing flash memories. At the beginning of convergence, the control gate is applied with a lower voltage. Thus, fewer current flows through the memory cell with ultra low threshold voltage. However, the threshold voltage of the memory cell is increasing, and the threshold voltages of the other memory cells are adjusted simultaneously. Next, the voltage applied to the control gate is increased. At this time, the number of the memory cells with ultra low or negative threshold voltage decreases, so the total current does not exceed the tolerance of the power supply, and the total current is not gathered in a memory cell. Thus, the threshold voltage of each flash memory cell is adjusted.

To achieve the above-mentioned object, the present invention provides a device for converging an erased flash memory array. The memory array includes a plurality of memory cells. Each memory cell comprises a control gate, a floating gate, a source, and drain. The drain voltage supply is coupled to the drain for providing a positive drain voltage. The constant current supply is coupled to the source for providing a source current. The control gate power supply is coupled to the control gate for providing a gradually increasing gate voltage to the control gate to control the source current flowing through the memory cell and adjust the threshold voltage of the memory cells.

Moreover, the present invention further provides a method for converging an erased flash memory array. The memory array includes a plurality of memory cells. Each memory cell comprises a control gate, a floating gate, a source, and drain. First, a positive drain voltage is provided to the drain. Next, a source current is provided to the source. Finally, a gradually increasing gate voltage is provided to the control gate to control the source current flowing through the memory cell and adjust the threshold voltage of the memory cells.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 shows the circuit to perform conventional converge process;

FIG. 2 shows the structure of the flash memory;

FIG. 3A shows the voltage applied to the control gate and the drain to perform the conventional converge process;

FIG. 3B shows the threshold voltage distribution of flash memory cells;

FIG. 4 shows the read disturb characteristics of 100&100K P/E cycled cell with conventional converge process;

FIG. 5 shows the circuit to perform converge process according to the embodiment of the present invention;

FIG. 6A shows the voltage applied to the control gate and the drain to perform convergence according to the embodiment of the present invention;

FIG. 6B shows the threshold voltage distribution of flash memory cells; and

FIG. 7 shows the read disturb characteristics of 100&100K P/E cycled cell with convergence according to the embodiment of the present invention.

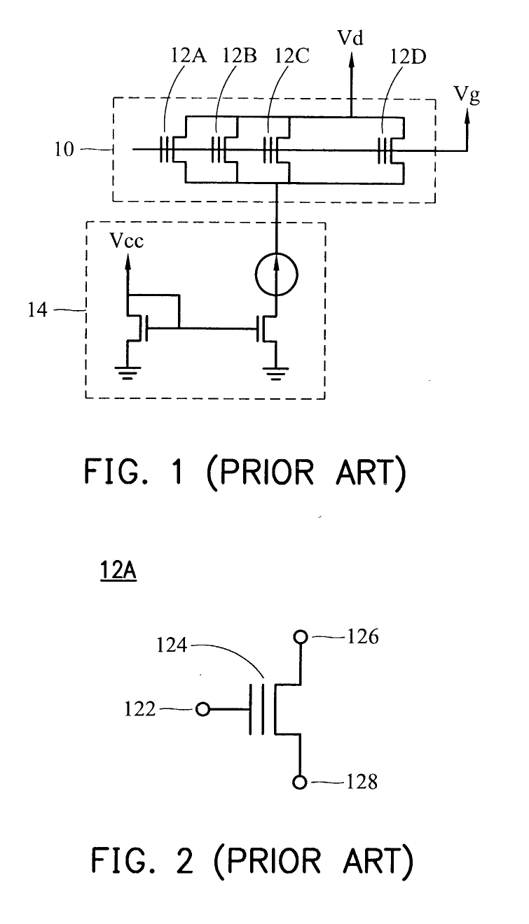

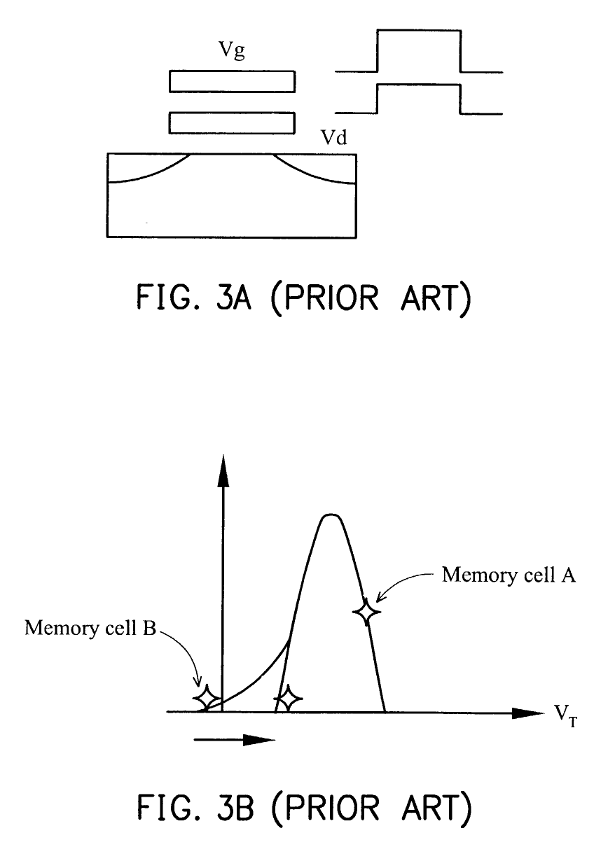

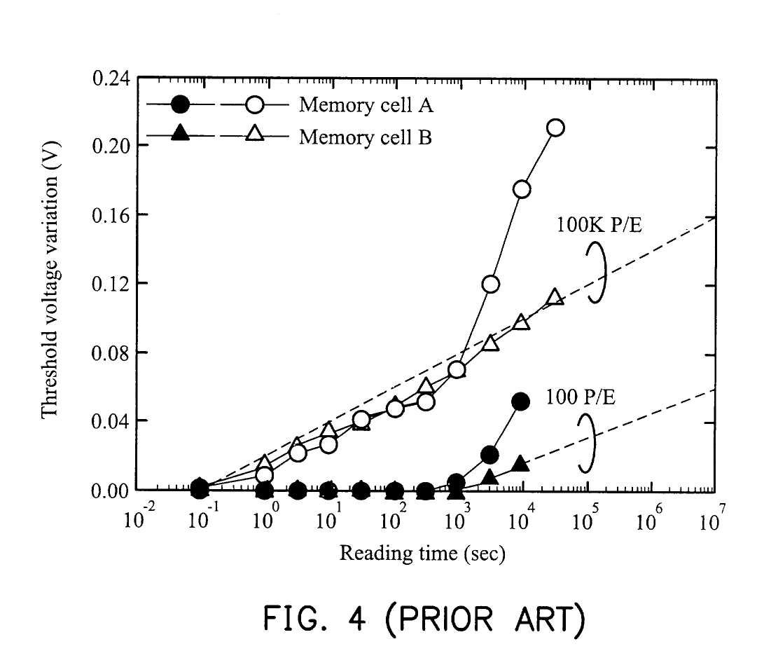

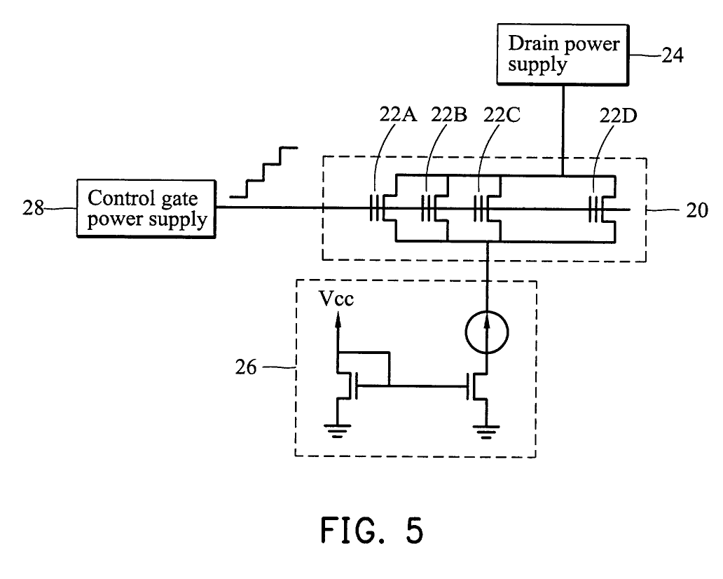

### DETAILED DESCRIPTION OF THE INVENTION

FIG. 5 shows the circuit to perform converge process according to the embodiment of the present invention. Memory array 20 comprises a plurality of memory cells 22A, 22B, 22C, and 22D. The memory cells are flash memories. The structure of the flash memory is shown in FIG. 2. Flash memory 22A comprises a control gate 122, a floating gate 124, a grain 126 and a source 128.

Drain power supply 24 provides voltage to the drains of the memory cells 22A, 22B, 22C, and 22D, the voltage is between from 2.5V to 5V. The source of the memory cells is connected to the constant current supply 26 to receive 100 uA˜2 mA current. In addition, the control gate of the memory cell is connected to the control gate power supply 28. The voltage provided by the control gate power supply 28 increases step by step. For example, the provided voltage is 0V, 0.3V, 0.6V, . . . , and 3V, wherein the variation is 0.3V. Thus, convergence according to the embodiment of the present invention is performed.

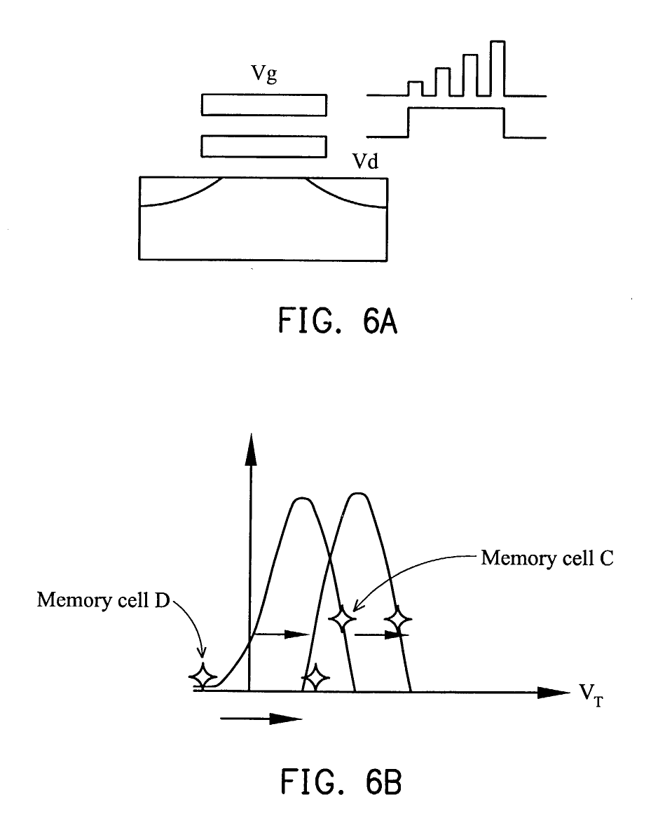

FIG. 6A shows the voltage applied to the control gate and the drain to perform convergence according to the embodiment of the present invention. FIG. 6B shows the threshold voltage distribution of flash memory cells.

At the beginning of convergence, the control gate is applied with a lower voltage. Thus, the threshold voltage of the memory cells with ultra low threshold voltage is adjusted, for example, memory cell D. Since the threshold voltage of the memory cell D is increased, the threshold voltage of the memory cell D will keep increasing when the control gate voltage is raised. Thus, the number of the memory cells with ultra low threshold voltage (memory cell D) is decreased. The threshold voltage of the other memory cells, for example, memory cell C, can be raised until the threshold voltage of the memory cell D is raised to normal value.

Moreover, the current flowing through all the memory cells is lower than the default current of the constant power supply because the threshold voltage is raised. Thus, convergence is performed successfully. Finally, the threshold voltages of all memory cells are adjusted. As shown in FIG. 6B, the curves of the memory cells C and D are all adjusted.

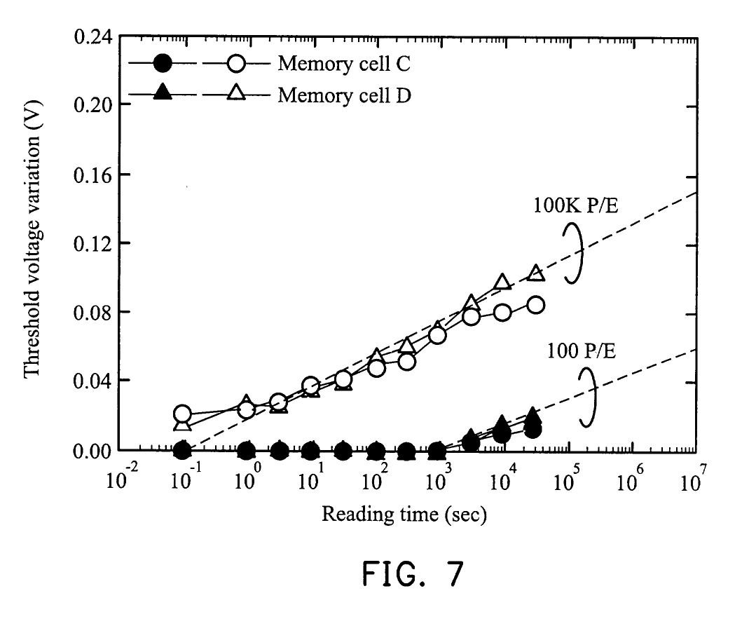

FIG. 7 shows the read disturb characteristics of 100&100K P/E cycled cell with convergence according to the embodiment of the present invention, cell dimension of which is W/L=0.3/0.3 um. Here, a stepping gate voltage and a constant drain voltage are applied to the memory cell C and D. Thus, the memory cell C and D are both soft-programmed. Intently, no abrupt threshold voltage shift increasing is observed. Thus, the reliability of the memory cells is improved by performing convergence according to the embodiment of the present invention.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A device for converging an erased flash memory array having a plurality of memory cells, each memory cell comprising a control gate, a floating gate, a source, and drain, the device comprising:
a drain voltage supply coupled to the drain for providing a positive drain voltage;
a constant current supply coupled to the source for providing a source current; and
a control gate power supply coupled to the control gate for providing a gradually increasing gate voltage to the control gate to control the source current flowing through the memory cell and adjust the threshold voltage of the memory cells.

2. The device for converging erased flash memories as claimed in claim 1, wherein the source current is between from 100 uA to 2 mA.

3. The device for converging erased flash memories as claimed in claim 1, wherein the gate voltage is increased step by step.

4. A method for converging an erased flash memory array having a plurality of memory cells, each memory cell comprising a control gate, a floating gate, a source, and drain, the method comprising the following steps:
providing a positive drain voltage to the drain;
providing a source current to the source; and
providing a gradually increasing gate voltage to the control gate to control the source current flowing through the memory cell and adjust the threshold voltage of the memory cells.

5. The method for converging erased flash memories as claimed in claim 4, wherein the source current is between 100 uA and 2 mA.

6. The method for converging erased flash memories as claimed in claim 4, wherein the gate voltage is increased step by step.
